(19) United States
(12) Patent Application Publication
(10) Pub. No.: US 2026/0047360 A1
(43) Pub. Date: Feb. 12, 2026

(54) SUBSTRATE PROCESSING METHOD, METHOD FOR MANUFACTURING SEMICONDUCTOR DEVICE, AND MICROWAVE PLASMA APPARATUS

(71) Applicant: Tokyo Electron Limited, Tokyo (JP)

(72) Inventors: Masashi IMANAKA, Yamanashi (JP); Makoto WADA, Yamanashi (JP); Kazuyoshi YAMAZAKI, Yamanashi (JP); Isao GUNJI, Yamanashi (JP)

(21) Appl. No.: 19/279,158

(22) Filed: Jul. 24, 2025

(30) Foreign Application Priority Data
Aug. 6, 2024 (JP) 2024-130131

(51) Int. Cl. H01L 21/02; H01J 37/32

(52) U.S. Cl. CPC H01L 21/02252; H01J 37/32266; H01J 37/32311; H01L 21/02126; H01L 21/0228; H01J 2237/338

(57) ABSTRACT

A substrate processing method includes the processes of preparing a substrate having a concave-convex structure, forming a dielectric film including at least silicon and nitrogen on the concavo-convex structure, to form the dielectric film having a non-uniform portion in a recess of the concavo-convex structure, and forming a protective film on a surface of the dielectric film by exposing the dielectric film to first plasma including an oxygen gas, to form the protective film including a cap layer that closes the non-uniform portion by bonding an upper side of the non-uniform portion of the concavo-convex structure.

### CROSS-REFERENCE TO RELATED APPLICATIONS

This application is based upon and claims priority to Japanese Patent Application No. 2024-130131, filed on Aug. 6, 2024, the entire contents of which are incorporated herein by reference.

### BACKGROUND

### 1. Field of the Invention

The present disclosure relates to substrate processing methods, methods for manufacturing semiconductor devices, and microwave plasma apparatuses.

### 2. Description of the Related Art

For example, Japanese Laid-Open Patent Publication No. 2022-165287 proposes a method for manufacturing a semiconductor device, including processing a substrate having a top surface and a side surface composed of a first material including a first element, and a recess formed in the surface of the substrate and having a bottom surface composed of a second material including a second element different from the first element. The method supplies a precursor to the substrate, and causes at least a portion of a molecular structure of molecules constituting the precursor to be adsorbed on the surface of the first material in the recess, thereby forming a deposition inhibition layer (or a film formation suppression layer) on the surface of the first material. The method supplies a film deposition substance to the substrate having the film deposition inhibition layer formed on the surface of the first material, so as to grow a film on the surface of the second material in the recess.

### SUMMARY

In one aspect, the present disclosure provides a substrate processing method, a method for manufacturing a semiconductor device, and a microwave plasma apparatus which embed a film in a recess.

According to an aspect of the present disclosure, a substrate processing method includes preparing a substrate having a concave-convex structure; forming a dielectric film including at least silicon and nitrogen on the concavo-convex structure, to form the dielectric film having a non-uniform portion in a recess of the concavo-convex structure; and forming a protective film on a surface of the dielectric film by exposing the dielectric film to first plasma including an oxygen gas, to form the protective film including a cap layer that closes the non-uniform portion by bonding an upper side of the non-uniform portion of the concavo-convex structure.

The object and advantages of the embodiments will be realized and attained by means of the elements and combinations particularly pointed out in the claims.

It is to be understood that both the foregoing general description and the following detailed description are exemplary and explanatory and not restrictive of the invention, as claimed.

### BRIEF DESCRIPTION OF THE DRAWINGS

FIG. 1 is a flow chart illustrating an example of a substrate processing method;

FIG. 2 is a schematic cross sectional view of an example of a substrate prepared in step S101;

FIG. 3 is a schematic cross sectional view of the example of the substrate after a process of step S102;

FIG. 4 is a schematic cross sectional view of the example of the substrate after a process of step S103;

FIG. 5 is a schematic cross sectional view of the example of the substrate after a process of step S104;

FIG. 6 is a schematic cross sectional view of the example of substrate after a process of step S105;

FIG. 7 is a schematic cross sectional view of the example of the substrate after a process of step S106;

FIG. 8 is a flow chart illustrating an example of a process of forming a cap layer;

FIG. 9 is a flow chart illustrating another example of the process of forming the cap layer;

FIG. 10 is a flow chart illustrating still another example of the process of forming the cap layer;

FIG. 11 is a flow chart illustrating a further example of the process of forming the cap layer;

FIG. 12 is a diagram illustrating an example of a microwave plasma apparatus for forming a cap layer; and

FIG. 13A, FIG. 13B, and FIG. 13C are cross sectional views illustrating examples of a processing result.

### DETAILED DESCRIPTION

Hereinafter, embodiments of the present disclosure will be described with reference to the drawings. In the drawings, the same constituent elements are designated by the same reference numerals, and a redundant description thereof may be omitted.

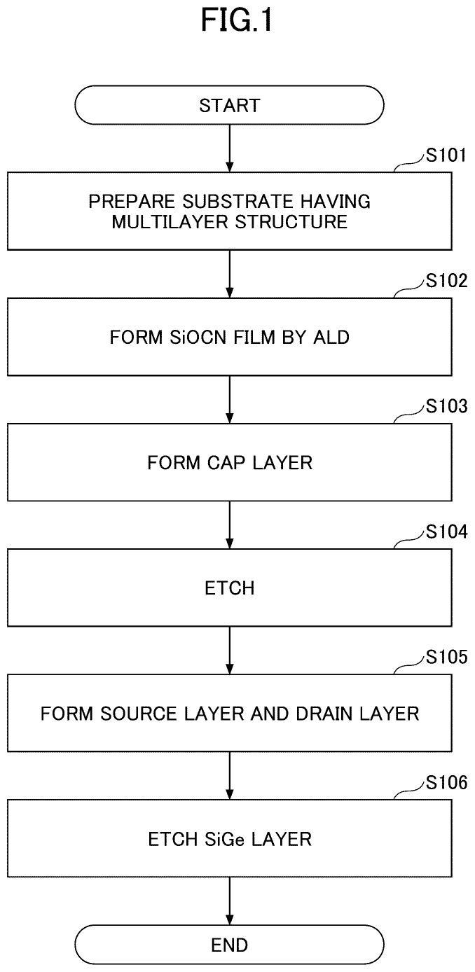

An example of a substrate processing method according to the present embodiment will be described with reference to FIG. 1. FIG. 1 is a flow chart illustrating an example of the substrate processing method.

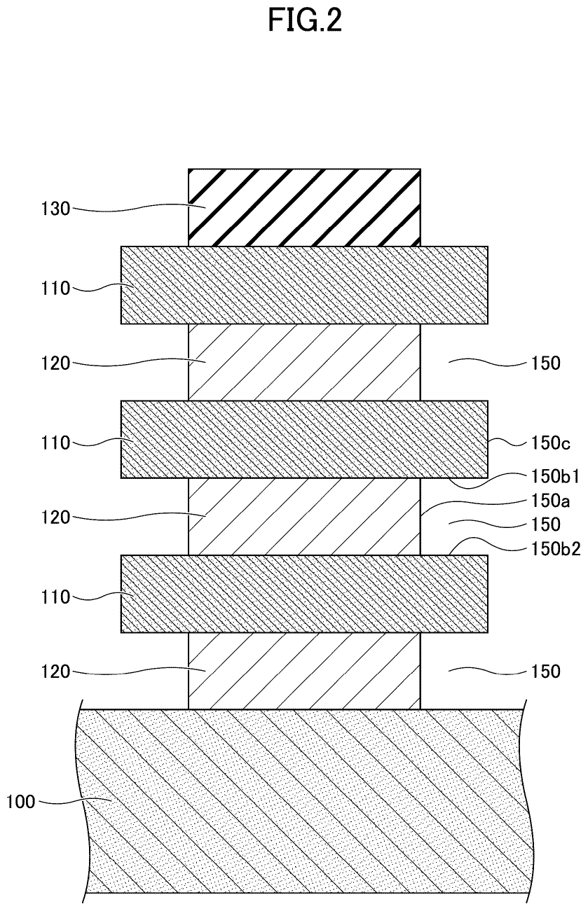

In step S101, a substrate having a multilayer structure (or a stacked structure) is prepared. FIG. 2 is a schematic cross sectional view of an example of the substrate prepared in step S101.

A multilayer structure, in which a first material layer (Si layer) 110 composed of a first material and a second material layer (SiGe layer) 120 composed of a second material are alternately stacked, is provided on a surface of a base material 100. In addition, an insulating layer 130 is provided above the multilayer structure of the first material layers 110 and the second material layers 120. In the multilayer structure of the first material layers 110 and the second material layers 120 of the example illustrated in FIG. 2, one second material layer 120 is formed as a lowermost layer in contact with the base material 100, and one first material layer 110 is formed as an uppermost layer in contact with the insulating layer 130.

The base material 100 is a silicon (Si) wafer, for example.

The first material includes a first element. The first element is silicon (Si), for example. In the following description, the first material layer 110 is described as a silicon (Si) layer.

The second material includes a first element and a second element. The first element is silicon (Si), for example, and the second element is germanium (Ge), for example. In the following description, the second material layer 120 is described as a silicon germanium (SiGe) layer.

The insulating layer 130 is composed of an insulator. Examples of the insulator used for the insulating layer 130 include silicon oxide (SiO₂), silicon nitride (SiN), or the like, for example.

A recess 150 is formed in a sidewall of the multilayer structure of the first material layer 110 and the second material layer 120. The recess 150 has a depth direction parallel to the surface of the base material 100. The direction parallel to the surface of the base material 100 in FIG. 2 is a horizontal direction, or a direction perpendicular to a stacking direction of the first material layer 110 and the second material layer 120 of the multilayer structure, or a direction perpendicular to the sidewall of the multilayer structure. Specifically, the recess 150 is formed by forming a sidewall of the second material layer 120 on an inner side of a sidewall of the first material layer 110. In other words, when viewed in the depth direction of the recess 150 (the horizontal direction in FIG. 2), a bottom surface 150a of the recess 150 is formed by the second material layer 120. Further, an upper side surface (one side surface) 150b1 of the recess 150, a lower side surface (the other side surface) 150b2 of the recess 150, and a top surface 150c of a protrusion between two adjacent recesses 150 are formed of the first material layer 110, respectively. In other words, the sidewall of the multilayer structure of the substrate has a concavo-convex structure in which the first material layer 110 forms a convex portion of the concavo-convex structure and the second material layer 120 forms the recess 150 of the concavo-convex structure.

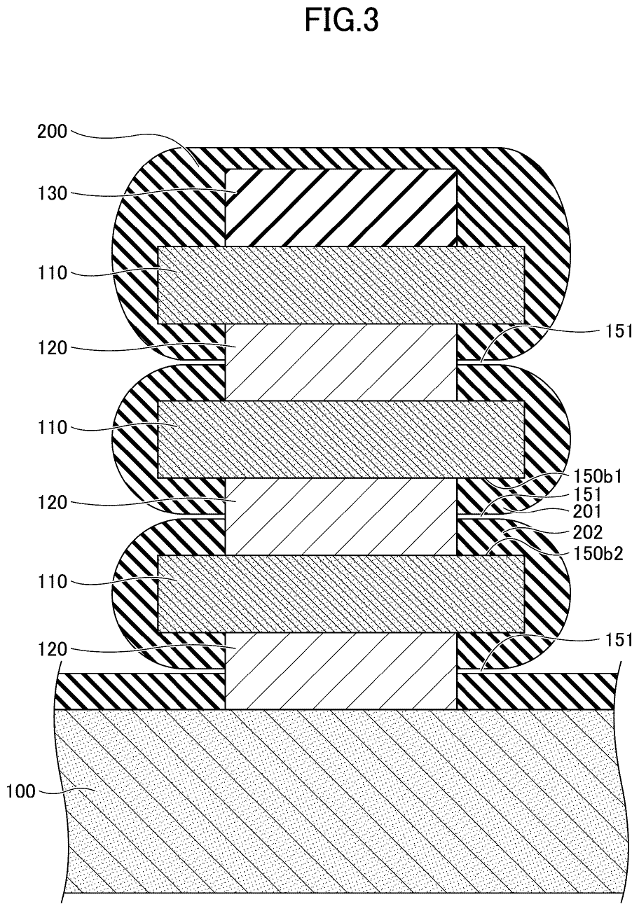

In step S102, a dielectric film (SiOCN film) 200 including at least silicon (Si) and nitride (N) is formed on the concavo-convex structure of the substrate by atomic layer deposition (ALD). FIG. 3 is a schematic cross sectional view of the example of the substrate after the process of step S102.

In this example, the dielectric film 200 including at least silicon (Si) and nitrogen (N) is formed by alternately supplying a precursor gas and a reaction gas. That is, a cycle including a process of supplying a precursor gas to the substrate and causing the precursor gas to be adsorbed on the surface of the concavo-convex structure and a process of supplying a reaction gas to the substrate and causing the reaction gas to react with the precursor gas adsorbed on the surface of the concavo-convex structure is repeated a predetermined number of times. Thus, the dielectric film 200 having a desired thickness can be formed by repeating the cycle. Further, the process of supplying the reaction gas may include processes of generating plasma of the reaction gas and causing active species (ions, radicals, or the like) of the reaction gas to react with the precursor gas adsorbed on the surface of the concavo-convex structure, so as to form the dielectric film 200.

The dielectric film 200 may include oxygen (O). The dielectric film 200 may include carbon (C). That is, the dielectric film 200 may be any one of a SiCN film, a SiON film, and a SiOCN film.

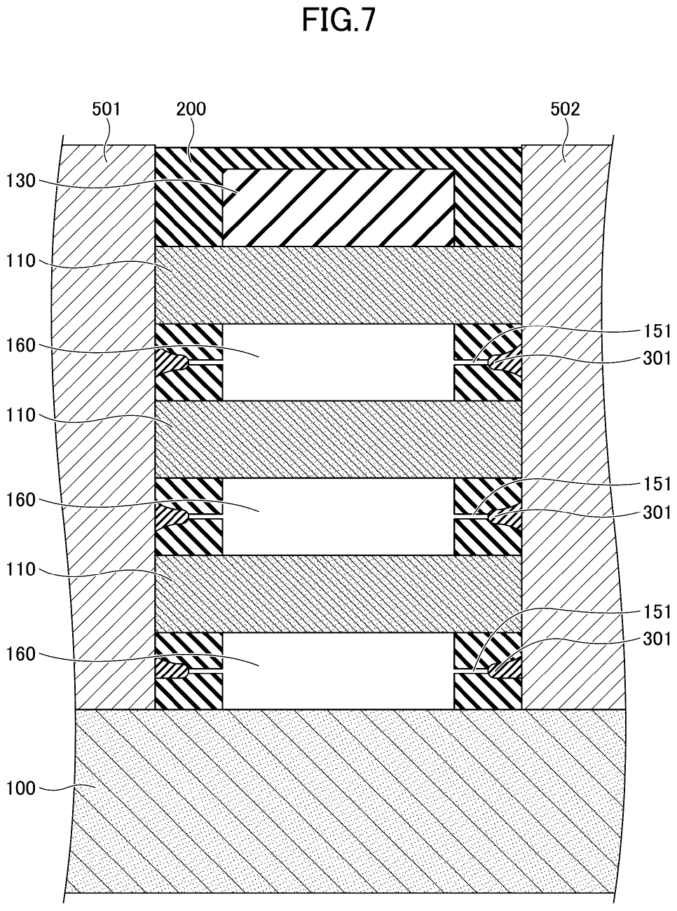

In addition, as illustrated in FIG. 7 which will be described later, the dielectric film 200 is an interlayer dielectric disposed between the first material layers 110, and is preferably a film composed of a low dielectric constant material (low-k film composed of a low-k material). Specifically, the dielectric film 200 is preferably a SiOCN film or a SiCN film. In the following description, the dielectric film 200 is described as being a SiOCN film.

By forming the dielectric film 200 using the ALD, it is possible to form a conformal dielectric film 200 along the concavo-convex structure, with respect to the concavo-convex structure formed on the sidewall of the multilayer structure of the first material layer 110 and the second material layer 120.

On the other hand, by performing the film deposition by the ALD when embedding the dielectric film 200 inside the recess 150, the dielectric film 200 is formed from the bottom surface 150a of the recess 150, and the dielectric film 200 is (dielectric films 201 and 202 are) also formed from the upper side surface 150b1 of the recess 150 and the lower side surface 150b2 of the recess 150.

For this reason, in the dielectric film 200 embedded inside the recess 150, a non-uniform portion 151 is formed. The non-uniform portion 151 includes a gap (an opening, a void, or the like) between the dielectric film 201 formed from the upper side surface (one side surface) 150b1 and the dielectric film 202 formed from the lower side surface (the other side surface) 150b2, a seam (not illustrated) where the dielectric film 201 formed from the upper side surface (one side surface) 150b1 and the dielectric film 202 formed from the lower side surface (the other side surface) 150b2 are joined, or the like. The non-uniform portion 151 formed between the dielectric film 201 and the dielectric film 202 may be a seam, or may be a gap (an opening, a void, or the like).

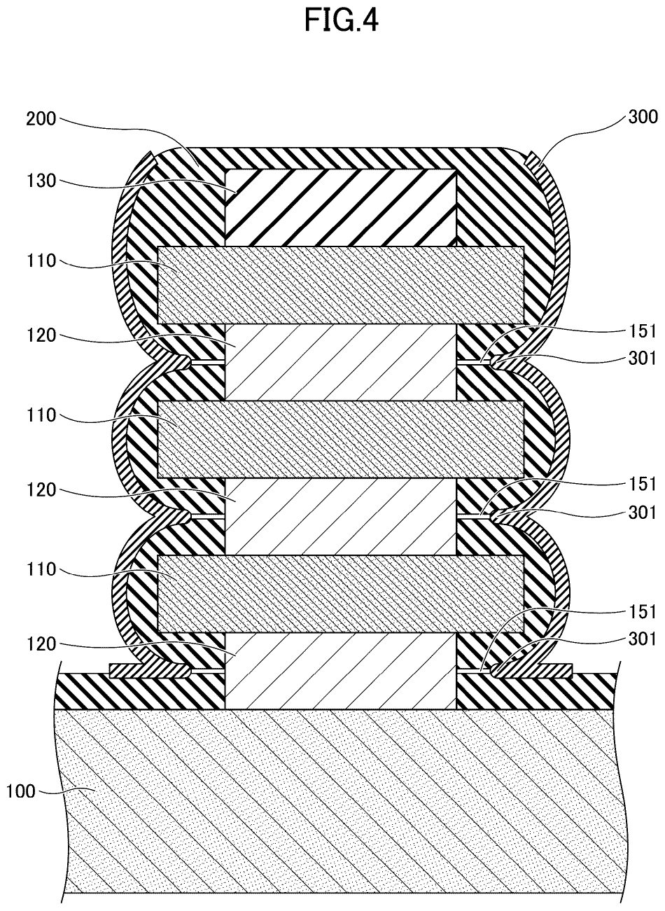

In step S103, a cap layer 301 is formed to close an entrance side of the non-uniform portion 151. FIG. 4 is a schematic cross sectional view of the example of the substrate after the process of step S103.

In this example, plasma of a gas including oxygen (O) is generated and supplied to the substrate, and the surface of the dielectric film 200 formed on the concavo-convex structure is exposed to the plasma of the gas including oxygen (O). Accordingly, nitrogen (N) in the dielectric film (SiOCN film) 200 is substituted with oxygen (O). That is, the surface of the dielectric film 200 is oxidized by oxygen plasma to form a protective film 300 on the surface of the dielectric film 200. Microwave plasma can be used as the plasma that forms the protective film 300.

In addition, as the protective film 300 is formed, the dielectric film 201 (refer to FIG. 3) formed from the upper side surface (one side surface) 150b1 of the recess 150 and the dielectric film 202 (refer to FIG. 3) formed from the lower side surface (the other side surface) 150b2 of the recess 150 are bonded (reformed) near the entrance of the non-uniform portion 151. Hence, the protective film 300 is formed with the cap layer 301 closing the entrance side of the non-uniform portion 151 (at the upper side when the depth direction of the recess 150 is viewed as a downward direction).

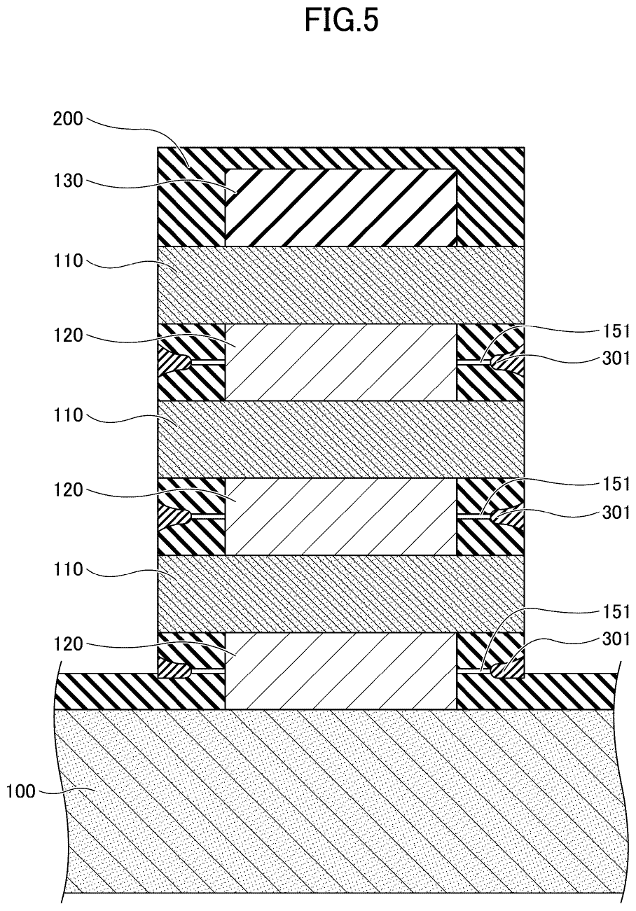

In step S104, an etching process is performed. FIG. 5 is a schematic cross sectional view of the example of the substrate after the process of step S104.

The dielectric film 200 and the protective film 300 are partially removed by the etching process. As a result, the right and left sidewalls (the top surface 150c illustrated in FIG. 2) of the first material layer 110 become exposed. On the other hand, the dielectric film 200 including the cap layer 301 is embedded inside the recess 150 (refer to FIG. 2). In addition, the non-uniform portion 151 of the dielectric film 200 is closed by the cap layer 301.

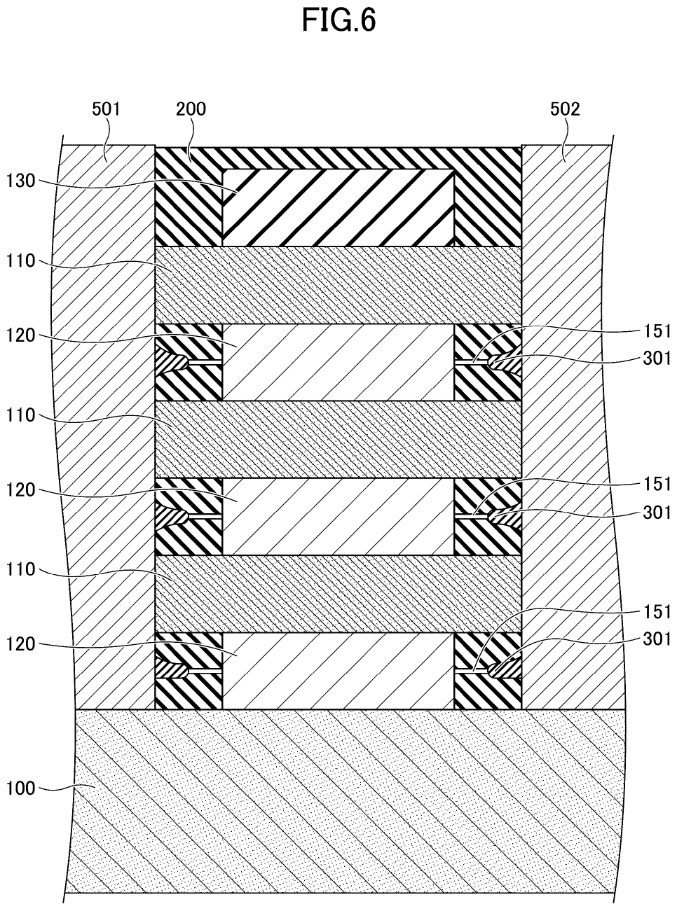

In step S105, a source layer 501 and a drain layer 502 are formed. FIG. 6 is a schematic cross sectional view of the example of the substrate after the process of step S105.

The source layer 501 and the drain layer 502 are composed of a conductive material, such as metal or the like, for example. The source layer 501 is formed so as to connect to one end of the first material layer 110. The drain layer 502 is formed so as to connect to the other end of the first material layer 110.

In step S106, the second material layer (SiGe layer) 120 is removed by an etching process.

FIG. 7 is a schematic cross sectional view of the example of the substrate after the process of step S106.

As illustrated in FIG. 7, the second material layer (SiGe layer) 120 is selectively removed from the multilayer structure of the first material layer (Si layer) 110 and the second material layer (SiGe layer) 120 by the etching process, thereby forming a cavity 160. The upper side and the outer side of the source layer 501 and the drain layer 502 are covered with a protective film (not illustrated) in advance, in order to prevent damage caused by the etching.

The dielectric film 200 including the cap layer 301 functions as an inner spacer for holding a nanosheet structure of the first material layer (Si layer) 110 when the second material layer (SiGe layer) 120 is removed to form the cavity 160. Moreover, the dielectric film 200 including the cap layer 301 also functions as an interlayer dielectric (low-k film) in a semiconductor device structure.

In this example, when etching the second material layer (SiGe layer) 120, an etchant may be taken into the non-uniform portion 151, such as the seam, the gap, or the like from the cavity 160 and reach the source layer 501 and the drain layer 502. In this case, the source layer 501 and the drain layer 502 may become damaged by the etching.

In contrast, in the present embodiment, the cap layer 301 is provided to close the non-uniform portion 151, and thus, the etchant taken into the non-uniform portion 151 from the cavity 160 is sealed by the cap layer 301. Accordingly, it is possible to prevent damage to the source layer 501 and the drain layer 502 during the etching of the second material layer (SiGe layer) 120.

Thereafter, the semiconductor device structure is formed by performing processes, such as a process of forming a gate layer or the like. A transistor having a gate all around (GAA) structure or the like is formed as the semiconductor device structure.

As described above, the protective film 300 can be formed by modifying the surface of the dielectric film (SiOCN film) 200 embedded in the recess 150 having the concavo-convex structure using oxygen plasma, and the cap layer 301 closing the non-uniform portion 151 can be formed (refer to steps S101 through S103).

Accordingly, it is possible to prevent damage to the source layer 501 and the drain layer 502 when etching the second material layer (SiGe layer) 120.

The substrate processing method illustrated in FIG. 2 may be performed by a substrate processing system. The substrate processing system may include a film forming apparatus that forms the dielectric film 200 on the substrate (refer to step S102), a microwave plasma apparatus that forms the protective film 300 using microwave plasma (refer to step S103), a first etching apparatus that removes a part of the dielectric film 200 and the protective film 300 (refer to step S104), a film forming apparatus that forms the source layer 501 and the drain layer 502 (refer to step S105), a second etching apparatus that etches the second material layer 120 (refer to step S106), and a control device that controls these apparatuses.

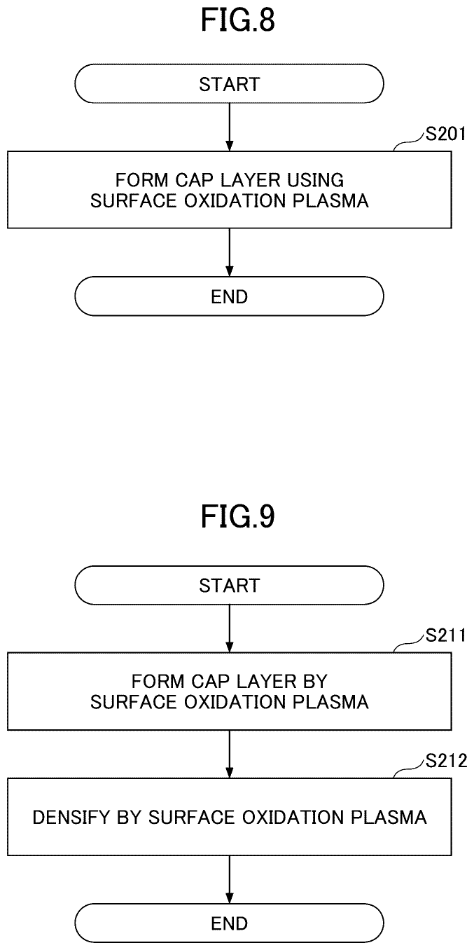

Next, a process of forming the cap layer 301 in step S103 will be described with reference to FIG. 8 through FIG. 11.

FIG. 8 is a flow chart illustrating an example of a process of forming the cap layer 301.

In step S201, the cap layer 301 is formed using surface oxidization plasma.

In this example, first plasma of the gas including oxygen (O) is generated and supplied to the substrate, and the surface of the dielectric film 200 formed on the concavo-convex structure is exposed to the first plasma of the gas including oxygen (O).

Hence, nitrogen (N) in the dielectric film (SiOCN film) 200 is substituted with oxygen (O). That is, the surface of the dielectric film 200 is oxidized by oxygen plasma to form the protective film 300 on the surface of the dielectric film 200. Microwave plasma can be used as the plasma that forms the protective film 300.

In addition, as the protective film 300 is formed, the dielectric film 201 (refer to FIG. 3) formed from the upper side surface (one side surface) 150b1 of the recess 150 and the dielectric film 202 (refer to FIG. 3) formed from the lower side surface (the other side surface) 150b2 of the recess 150 are bonded (reformed) near the entrance of the non-uniform portion 151. Accordingly, the protective film 300 is formed with the cap layer 301 closing the entrance side of the non-uniform portion 151 (at the upper side when the depth direction of the recess 150 is viewed as the downward direction).

The following illustrates an example of a recipe of the first plasma.

### First Plasma

Pressure inside processing chamber: 200 Pa to 1000 Pa
Processing gas: O₂ gas (100 sccm to 1000 sccm)
Microwave power: 2000 W to 4000 W

FIG. 9 is a flow chart illustrating another example of the process of forming the cap layer 301.

In step S211, the cap layer 301 is formed by surface oxidation plasma.

In this example, similar to step S201, the first plasma of the gas including oxygen (O) is generated and supplied to the substrate, and the surface of the dielectric film 200 formed on the concavo-convex structure is exposed to the first plasma of the gas including oxygen (O). Hence, nitrogen (N) in the dielectric film (SiOCN film) 200 is substituted with oxygen (O). That is, the surface of the dielectric film 200 is oxidized by oxygen plasma to form the protective film 300 on the surface of the dielectric film 200. Microwave plasma can be used as the plasma that forms the protective film 300.

In addition, as the protective film 300 is formed, the dielectric film 201 (refer to FIG. 3) formed from the upper side surface (one side surface) 150b1 of the recess 150 and the dielectric film 202 (refer to FIG. 3) formed from the lower side surface (the other side surface) 150b2 of the recess 150 are bonded (reformed) near the entrance of the non-uniform portion 151. Accordingly, the protective film 300 is formed with the cap layer 301 closing the entrance side of the non-uniform portion 151 (at the upper side when the depth direction of the recess 150 is viewed as the downward direction).

In step S212, the protective film 300 including the cap layer 301 is densified (increased in density) by the surface oxidation plasma.

In this example, second plasma of the gas including oxygen (O) is generated and supplied to the substrate, and the surface of the dielectric film 200 formed on the concavo-convex structure is exposed to the second plasma of the gas including oxygen (O). Thus, the protective film 300 including the cap layer 301 is densified. This densification of the protective film 300 can improve an etching resistance of the cap layer 301 with respect to the etchant used in the process of step S106. In addition, it is possible to prevent damage to the source layer 501 and the drain layer 502 when etching the second material layer (SiGe layer) 120. Microwave plasma can be used as the plasma that densifies the protective film 300.

In this example, the first plasma is generated at a higher pressure and a higher O₂ concentration than the second plasma. Accordingly, “O3p” becomes dominant in the radical species generated by the first plasma. The radical species react deep into the dielectric film 200, thereby making it possible to suitably form the cap layer 301.

The second plasma is generated at a lower pressure and a lower O₂ concentration than the first plasma. Further, the H₂ gas may be added to the O₂ gas. Accordingly, “O1d” becomes dominant in the radical species generated by the second plasma. In addition, when the H₂ gas is added, OH radicals are also generated. These radical species remove hydrogen (H) from the dielectric film 200 and the protective film 300, thereby densifying (increasing in density) the dielectric film 200 and the protective film 300 (including the cap layer 301).

The following illustrates an example of a recipe of the second plasma.

### Second Plasma

Pressure inside processing chamber: 60 Pa to 160 Pa
Processing gas: O₂ gas (5 sccm to 50 sccm)
H₂ gas (0 sccm to 10 sccm)
Microwave power: 2000 W to 4000 W

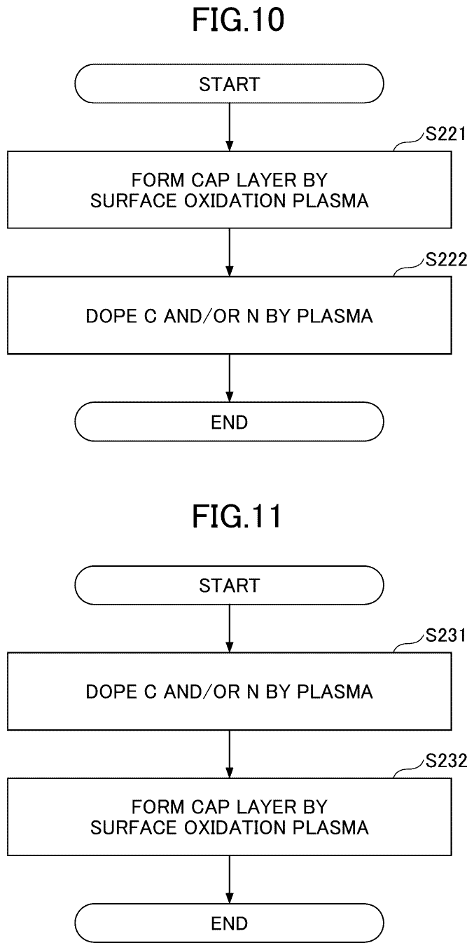

FIG. 10 is a flow chart illustrating still another example of the process of forming the cap layer 301.

In step S221, the cap layer 301 is formed by surface oxidation plasma.

In this example, similar to steps S201 and S211, the first plasma of the gas including oxygen (O) is generated and supplied to the substrate, and the surface of the dielectric film 200 formed on the concavo-convex structure is exposed to the first plasma of the gas including oxygen (O). Hence, nitrogen (N) in the dielectric film (SiOCN film) 200 is substituted with oxygen (O). That is, the surface of the dielectric film 200 is oxidized by oxygen plasma to form the protective film 300 on the surface of the dielectric film 200. Microwave plasma can be used as the plasma that forms the protective film 300.

In addition, as the protective film 300 is formed, the dielectric film 201 (refer to FIG. 3) formed from the upper side surface (one side surface) 150b1 of the recess 150 and the dielectric film 202 (refer to FIG. 3) formed from the lower side surface (the other side surface) 150b2 of the recess 150 are bonded (reformed) near the entrance of the non-uniform portion 151. Accordingly, the protective film 300 is formed with the cap layer 301 closing the entrance side of the non-uniform portion 151 (at the upper side when the depth direction of the recess 150 is viewed as the downward direction).

In step S222, the protective film 300 including the cap layer 301 is doped with carbon (C) and/or nitrogen (N) by third plasma including a carbon-containing gas and/or a nitrogen-containing gas.

By generating plasma of the carbon (C)-containing gas and exposing the substrate to the plasma of the carbon (C)-containing gas, the dielectric film 200 and the protective film 300 (including the cap layer 301) are doped with carbon (C). Examples of the carbon (C)-containing gas include a hydrocarbon (CₓH_{y}) gas or the like. Microwave plasma can be used as the plasma that dopes the dielectric film 200 and the protective film 300 (including the cap layer 301).

By generating plasma of the nitrogen (N)-containing gas and exposing the substrate to the plasma of the nitrogen (N)-containing gas, the dielectric film 200 and the protective film 300 (including the cap layer 301) are doped with nitrogen (N). Examples of the nitrogen (N)-containing gas include an ammonia (NH₃) gas or the like. Microwave plasma can be used as the plasma that dopes the dielectric film 200 and the protective film 300 (including the cap layer 301).

The following illustrates an example of a recipe of the third plasma.

### Third Plasma

Pressure inside processing chamber: 10 Pa to 1000 Pa
Process gas: Carbon-containing gas (CₓH_{y} gas (1 sccm to 100 sccm))
Nitrogen-containing gas (N₂ gas (10 sccm to 500 sccm))
Microwave power: 1500 W to 4000 W

In step S221, when the protective film 300 including the cap layer 301 is formed on the dielectric film 200, nitrogen (N) and carbon (C) in the films 200 and 300 are desorbed. For this reason, in step S222, a concentration ratio (composition ratio) of carbon (C) and/or nitrogen (N) in the films 200 and 300 can be adjusted by doping carbon (C) and/or nitrogen (N) into the dielectric film 200 and the protective film 300 (including the cap layer 301). In this case, it is possible to adjust the dielectric constant of the dielectric film 200 including the cap layer 301 used as an interlayer dielectric (low-k film).

FIG. 11 is a flow chart illustrating a further example of the process of forming the cap layer 301.

In step S231, the dielectric film 200 is doped with carbon (C) and/or nitrogen (N) by fourth plasma including a carbon (C)-containing gas and/or a nitrogen (N)-containing gas.

The dielectric film 200 is doped with carbon (C) by generating plasma of a carbon (C)-containing gas and exposing the substrate to the plasma of the carbon (C)-containing gas. Examples of the carbon (C)-containing gas include a hydrocarbon (CₓH_{y}) gas or the like. Microwave plasma can be used as the plasma that dopes the dielectric film 200.

The dielectric film 200 is doped with nitrogen (N) by generating plasma of a nitrogen (N)-containing gas and exposing the substrate to the plasma of the nitrogen (N)-containing gas. Examples of the nitrogen-containing gas include ammonia (NH₃) gas or the like. Microwave plasma can be used as the plasma that dopes the dielectric film 200.

The following illustrates an example of a recipe of the fourth plasma.

### Fourth Plasma

Pressure inside processing chamber: 10 Pa to 1000 Pa
Process gas: Carbon-containing gas (CₓH_{y} gas (1 sccm to 100 sccm))
Nitrogen-containing gas (N₂ gas (10 sccm to 500 sccm))
Microwave power: 1500 W to 4000 W

In step S232, the cap layer 301 is formed by surface oxidation plasma.

In this example, similar to steps S201, S211, and S221, the first plasma of the gas including oxygen (O) is generated and supplied to the substrate, and the surface of the dielectric film 200 formed on the concavo-convex structure is exposed to the first plasma of the gas including oxygen (O). Hence, nitrogen (N) in the dielectric film (SiOCN film) 200 is substituted with oxygen (O). That is, the surface of the dielectric film 200 is oxidized by oxygen plasma to form the protective film 300 on the surface of the dielectric film 200. Microwave plasma can be used as the plasma that forms the protective film 300.

In addition, as the protective film 300 is formed, the dielectric film 201 (refer to FIG. 3) formed from the upper side surface (one side surface) 150b1 of the recess 150 and the dielectric film 202 (refer to FIG. 3) formed from the lower side surface (the other side surface) 150b2 of the recess 150 are bonded (reformed) near the entrance of the non-uniform portion 151. Accordingly, the protective film 300 is formed with the cap layer 301 closing the entrance side of the non-uniform portion 151 (at the upper side when the depth direction of the recess 150 is viewed as the downward direction).

By doping the surface of the dielectric film 200 with nitrogen (N) in advance, it is possible to promote bonding between the dielectric film 201 and the dielectric film 202, and to suitably form the cap layer 301.

Further, by doping the dielectric film 200 with carbon (C) and/or nitrogen (N) in advance, it is possible to adjust the concentration ratio (composition ratio) of carbon (C) and/or nitrogen (N) in the dielectric film 200 and the protective film 300 after the protective film 300 is formed. Hence, it is possible to adjust the dielectric constant of the dielectric film 200 including the cap layer 301 used as an interlayer dielectric (low-k film).

In step S231, the dielectric film 200 is doped with carbon (C) and/or nitrogen (N) by the plasma, but the present disclosure is not limited thereto. For example, a dielectric film adjusted to increase the concentration of carbon (C) and/or nitrogen (N) may be formed on the surface of the dielectric film 200 by ALD. In this case, the concentration ratio (composition ratio) of carbon (C) and/or nitrogen (N) in the protective film 300 including the cap layer 301 can be adjusted by increasing the concentration of carbon (C) and/or nitrogen (N) on the surface of the dielectric film 200 in advance.

### Microwave Plasma Apparatus

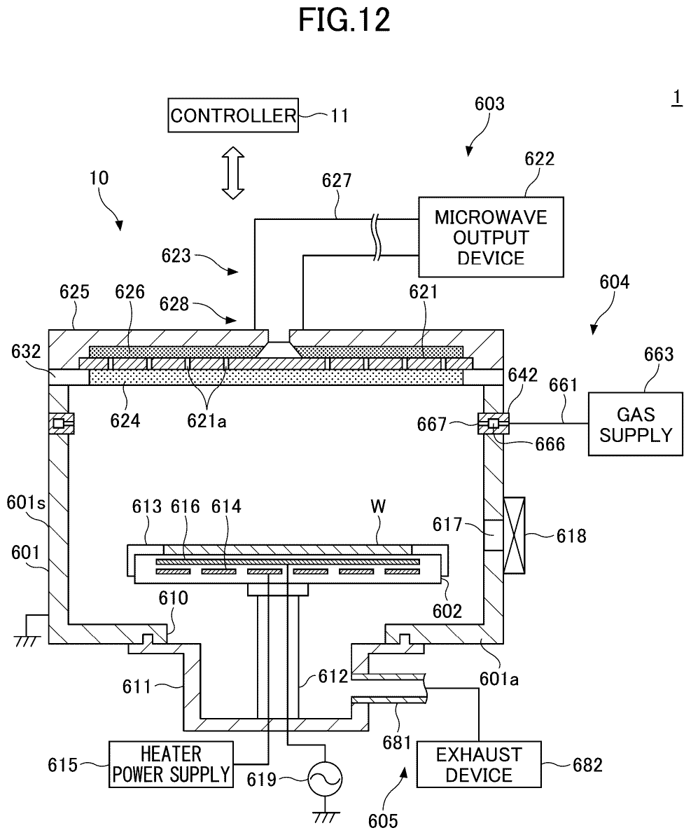

Next, a microwave plasma apparatus 1 that performs the process of forming the cap layer 301 in step S103 will be described with reference to FIG. 12. FIG. 12 is a schematic cross sectional view illustrating an example of the microwave plasma apparatus 1 according to an embodiment of the present disclosure. The microwave plasma apparatus 1 illustrated in FIG. 12 is configured as a radial line slot antenna (RLSA: registered trademark) microwave plasma type plasma processing apparatus, for example.

The microwave plasma apparatus 1 includes an apparatus main body 10 and a controller 11 that controls the apparatus main body 10. The apparatus main body 10 includes a chamber 601, a stage 602, a microwave introduction mechanism 603, a gas supply mechanism 604, and an exhaust mechanism 605.

The chamber 601 has an approximately cylindrical shape, and an opening 610 is formed at an approximate center of a bottom wall 601a of the chamber 601. An exhaust chamber 611 that communicates with the opening 610 and protrudes downward is provided in the bottom wall 601a. An opening 617 through which a substrate W passes is formed in a sidewall 601s of the chamber 601, and the opening 617 is opened and closed by a gate valve 618. The chamber 601 is an example of a processing chamber.

The substrate W to be processed is placed on the stage 602. The stage 602 has an approximately disk shape, and is formed of ceramics, such as AlN or the like. The stage 602 is supported by a cylindrical support member 612 composed of ceramics, such as AlN or the like, and extending upward from an approximate center of a bottom of the exhaust chamber 611. An edge ring 613 is provided at an outer edge portion of the stage 602 so as to surround the substrate W placed on the stage 602. Further, raising and lowering pins (not illustrated) for raising and lowering the substrate W are provided inside the stage 602, and these raising and lowering pins can protrude and retract relative to a top surface of the stage 602.

In addition, a resistance heating type heater 614 is embedded inside the stage 602, and the heater 614 heats the substrate W placed on the stage 602 according to power supplied from a heater power supply 615. A thermocouple (not illustrated) is inserted into the stage 602, and a temperature of the substrate W can be controlled between 350° C. and 850° C., for example, based on a signal from the thermocouple. Moreover, an electrode 616 having a size approximately the same as that of the substrate W is embedded inside the stage 602 above the heater 614, and a bias power supply 619 is electrically connected to the electrode 616. The bias power supply 619 supplies bias power of a predetermined frequency and magnitude to the electrode 616. Ions are attracted to the substrate W placed on the stage 602 due to the bias power supplied to the electrode 616. The bias power supply 619 may be omitted depending on characteristics of the plasma processing.

The microwave introduction mechanism 603 is provided at an upper portion of the chamber 601, and includes an antenna 621, a microwave output device 622, and a microwave transmission mechanism 623. The antenna 621 has a plurality of slots 621a, which are through holes. The microwave output device 622 outputs microwaves. The microwave transmission mechanism 623 guides the microwaves output from the microwave output device 622 to the antenna 621.

A dielectric window 624 formed of a dielectric is provided below the antenna 621. The dielectric window 624 is supported by a ring shaped support member 632 provided at the upper portion of the chamber 601. A slow wave plate 626 is provided on the antenna 621. A shield member 625 is provided on the antenna 621. A flow path (not illustrated) is provided inside the shield member 625, and the shield member 625 cools the antenna 621, the dielectric window 624, and the slow wave plate 626 by a fluid, such as water or the like, flowing through the flow path.

The antenna 621 is formed of a copper plate, an aluminum plate, or the like having a silver plated surface or a gold plated surface, for example, and the plurality of slot 621a for emitting the microwaves are arranged in a predetermined pattern. The arrangement pattern of the plurality of slots 621a is set appropriately so that the microwaves are emitted uniformly. An example of a suitable pattern is a radial line slot in which a plurality of pairs of slots 621a are disposed concentrically, with each pair formed by two slots 621a disposed in a T-shape. A length and arrangement intervals of the plurality of slots 621a are determined appropriately according to an effective wavelength (λ_{g}) of the microwaves. In addition, the plurality of slots 621a may have other shapes, such as a circular shape, an arcuate shape, or the like. Further, the slot arrangement of the plurality of slots 621a is not particularly limited, and the plurality of slots 621a may be arranged in shapes other than the concentric shape, such as a spiral shape, a radial shape, or the like, for example. The pattern of the plurality of slots 621a is set appropriately so that microwave emission properties can obtain a desired plasma density distribution.

The slow wave plate 626 is formed of a dielectric material having a dielectric constant larger than that of vacuum, such as quarts, ceramics (Al₂O₃), polytetrafluoroethylene, polyimide, or the like. The slow wave plate 626 has a function of making the antenna 621 smaller by making the wavelength of the microwaves shorter than that in vacuum. The dielectric window 624 is also composed of the same dielectric material that forms the slow wave plate 626.

Thicknesses of the dielectric window 624 and the slow wave plate 626 are adjusted so that an equivalent circuit formed by the slow wave plate 626, the antenna 621, the dielectric window 624, and the plasma satisfies a resonance condition. By adjusting the thickness of the slow wave plate 626, a phase of the microwaves can be adjusted. By adjusting the thickness of the slow wave plate 626 so that the joint portion of the antenna 621 becomes an “antinode” of a standing wave, reflection of the microwaves can be minimized, while an emitted microwave energy can be maximized. In addition, by forming the slow wave plate 626 and the dielectric window 624 of the same material, it is possible to prevent interface reflection of the microwave.

The microwave output device 622 includes a microwave oscillator. The microwave oscillator may be a magnetron type or a solid state type microwave oscillator. A frequency of the microwaves generated by the microwave oscillator is in a range of 300 MHz to 10 GHz, for example. As an example, the microwave output device 622 outputs microwaves of 2.45 GHz by the magnetron microwave oscillator. The microwaves are an example of electromagnetic waves.

The microwave transmission mechanism 623 includes a waveguide 627 and a coaxial waveguide 628, and may further include a mode conversion mechanism. The waveguide 627 guides the microwaves output from the microwave output device 622. The coaxial waveguide 628 includes an inner conductor connected to the center of the antenna 621, and an outer conductor outside the inner conductor. The mode conversion mechanism is provided between the waveguide 627 and the coaxial waveguide 628. The microwaves output from the microwave output device 622 propagates inside the waveguide 627 in a transverse electric (TE) mode, and is converted from the TE mode to a transverse electromagnetic (TEM) mode by the mode conversion mechanism. The microwaves converted into the TEM mode propagate to the slow wave plate 626 through the coaxial waveguide 628, and are emitted from the slow wave plate 626 into the chamber 601 through the slots 621a of the antenna 621 and the dielectric window 624. A tuner (not illustrated) for matching an impedance of a load (plasma) inside the chamber 601 to an output impedance of the microwave output device 622 is provided in a middle of the waveguide 627.

The gas supply mechanism 604 includes a shower ring 642 provided in a ring shape along the inner wall of the chamber 601. The shower ring 642 has a ring shaped flow path 666 provided therein, and a plurality of discharge ports 667 connected to the flow path 666 and opening toward the inside of the chamber 601. A gas supply 663 is connected to the flow path 666 through a pipe 661. The gas supply 663 is provided with a plurality of gas sources and a plurality of flow controllers. In one embodiment, the gas supply 663 is configured to supply at least one processing gas from a corresponding gas source to the shower ring 642 through a corresponding flow controller. The processing gas supplied to the shower ring 642 is supplied into the chamber 601 through the plurality of discharge ports 667.

In addition, in a case where a graphene film is formed on the substrate W, the gas supply 663 supplies an oxygen gas and a noble gas controlled to have predetermined flow rates into the chamber 601 through the shower ring 642. In the present embodiment, the oxygen gas is a O₂ gas, for example. In the present embodiment, the noble gas is an argon (Ar) gas, for example.

The exhaust mechanism 605 includes an exhaust chamber 611, an exhaust pipe 681 installed in a sidewall of the exhaust chamber 611, and an exhaust device 682 connected to the exhaust pipe 681. The exhaust device 682 includes a vacuum pump, a pressure control valve, or the like.

The controller 11 includes a memory, a processor, and an input/output interface. The memory stores one or more programs to be executed by the processor, and one or more recipes including conditions of processes to be performed. The processor executes the program read from the memory, and controls various parts of the apparatus main body 10 through the input/output interface based on the one or more recipes stored in the memory.

For example, the controller 11 controls various parts of the microwave plasma apparatus 1 so as to form the cap layer 301 described above. In a detailed example, the controller 11 performs a preparation process (or step) of loading the substrate W having the dielectric film 200 embedded in the recess 150 and including the non-uniform portion 151 into the chamber 601. The controller 11 performs a process (or step) of supplying the gas including oxygen into the chamber 601, forming the protective film 300 on the surface of the dielectric film 200 by plasma of the gas including oxygen, and forming the protective film 300 including the cap layer 301 that closes the non-uniform portion 151 by bonding the upper side of the non-uniform portion 151.

The microwave plasma apparatus 1 performs processes (or steps S103, S201, S211, S221, and S232) of generating the first plasma and forming the protective film 300 including the cap layer 301 on the substrate W. Further, the microwave plasma apparatus 1 may be configured to perform a process (or step S212) of generating the second plasma and processing the substrate W, a process (or step S222) of generating the third plasma and processing the substrate W, and a process (or step S231) of generating the fourth plasma and processing the substrate W.

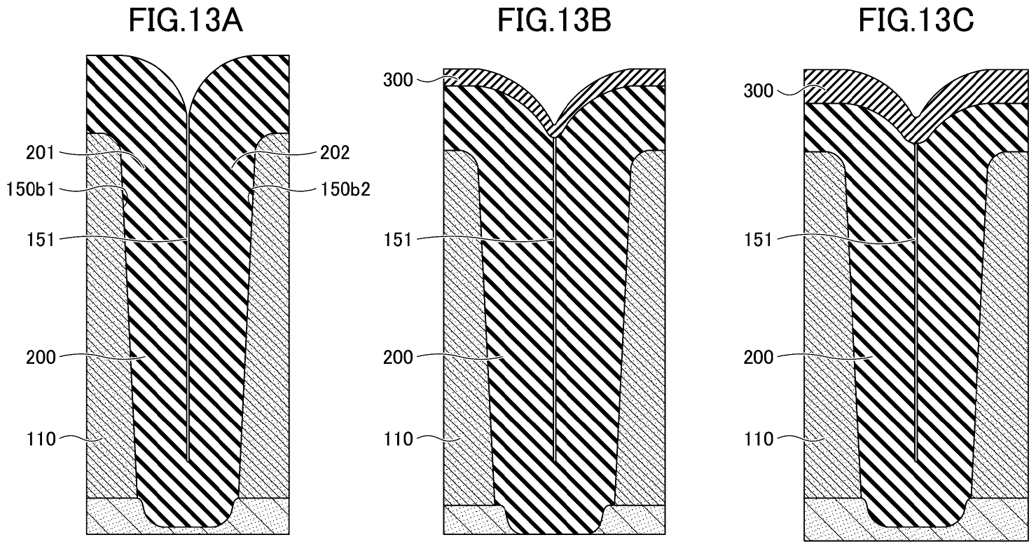

Next, a process of forming the protective film 200 by the plasma of the gas including oxygen (O) will be described with reference to FIG. 13A, FIG. 13B, and FIG. 13C. FIG. 13A through FIG. 13C are cross sectional views illustrating examples of a processing result.

FIG. 13A is an example of a transmission electron microscope (TEM) image after forming a SiOCN film. In this example, the SiOCN film (dielectric film 200) was formed by ALD on a Si layer (first material layer 110) having the recess formed by the process of step S102. Thus, the SiOCN film is embedded in the recess of the Si layer. Because the SiOCN film (dielectric film 200) is formed from the bottom of the recess and the upper side surface 150b1 and the lower side surface 150b2 of the recess, the non-uniform portion 151 including the seam, the gap, or the like is formed.

FIG. 13B and FIG. 13C are examples of TEM images after forming the protective film 300. In these examples, the plasma of the gas including oxygen (O) is generated by the process of step S103, and the surface of the SiOCN film (dielectric film 200) is exposed to the plasma of the gas including oxygen (O). Thus, the protective film 200 is formed.

In FIG. 13B, a gas mixture including 1746 sccm of an Ar gas and 54 sccm of a O₂ gas was used as the gas including oxygen (O), the plasma was generated at 1 Torr, and the surface of the SiOCN film (dielectric film 200) was exposed to the plasma during a time of 1260 seconds (sec).

In FIGS. 13C, 1000 sccm of a O₂ gas was used as the gas including oxygen (O), the plasma was generated at 5 Torr, and the surface of the SiOCN film (dielectric film 200) was exposed to the plasma during a time of 1260 sec.

As illustrated in FIG. 13A, FIG. 13B, and FIG. 13C by contrast, the non-uniform portion 151 including the seam, the gap, or the like is closed by forming the protective film 300.

In addition, as illustrated in FIG. 13B and FIG. 13C by contrast, the protective film 200 can be formed deeper as the pressure and the oxygen amount become higher.

According to an aspect, it is possible to provide a substrate processing method, a method for manufacturing a semiconductor device, and a microwave plasma apparatus which embed a film in a recess.

While certain embodiments have been described for forming a dielectric film on a concavo-convex structure, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A substrate processing method comprising:
preparing a substrate having a concave-convex structure;
forming a dielectric film including at least silicon and nitrogen on the concavo-convex structure, to form the dielectric film having a non-uniform portion in a recess of the concavo-convex structure; and
forming a protective film on a surface of the dielectric film by exposing the dielectric film to first plasma including an oxygen gas, to form the protective film including a cap layer that closes the non-uniform portion by bonding an upper side of the non-uniform portion of the concavo-convex structure.

2. The substrate processing method as claimed in claim 1, wherein the first plasma substitutes nitrogen in the dielectric film with oxygen.

3. The substrate processing method as claimed in claim 1, further comprising:
after the forming the protective film including the cap layer, modifying the cap layer by exposing the cap layer to second plasma including an oxygen gas,
wherein the second plasma is different from the first plasma.

4. The substrate processing method as claimed in claim 3, wherein the second plasma increases a film density of the cap layer.

5. The substrate processing method as claimed in claim 1, further comprising:
after the forming the protective film including the cap layer, modifying the protective film by exposing the protective film to a third plasma including a carbon-containing gas and/or a nitrogen-containing gas.

6. The substrate processing method as claimed in claim 5, wherein the third plasma dopes the protective film with carbon and/or nitrogen.

7. The substrate processing method as claimed in claim 1, further comprising:
after the forming the dielectric film and before the forming the protective film including the cap layer, modifying the dielectric film by exposing the dielectric film to a fourth plasma including a carbon-containing gas and/or a nitrogen-containing gas.

8. The substrate processing method as claimed in claim 7, wherein the fourth plasma dopes the dielectric film with carbon and/or nitrogen.

9. The substrate processing method as claimed in claim 1, wherein the first plasma is microwave plasma.

10. The substrate processing method as claimed in claim 1, wherein the forming the dielectric film forms the dielectric film by atomic layer deposition.

11. The substrate processing method as claimed in claim 1, wherein the dielectric film is a SiOCN film or a SiCN film.

12. A method for manufacturing a semiconductor device, comprising:
preparing a substrate having a multilayer structure in which Si layers and SiGe layers are alternately stacked, and a sidewall of the multilayer structure has a concavo-convex structure in which the Si layer forms a convex portion of the concavo-convex structure and the SiGe layer forms a recess of the concavo-convex structure;
forming a dielectric film including at least silicon and nitrogen on the concavo-convex structure, to form the dielectric film having a non-uniform portion in the recess of the concavo-convex structure; and
forming a protective film on a surface of the dielectric film by exposing the dielectric film to first plasma including an oxygen gas, to form the protective film including a cap layer that closes the non-uniform portion of the concavo-convex structure by bonding an upper side of the non-uniform portion.

13. A microwave plasma apparatus comprising:
a processing chamber;
a stage disposed inside the processing chamber and configured to receive a substrate placed thereon;
a gas supply mechanism configured to supply a processing gas into the processing chamber;
a microwave introduction mechanism configured to generate plasma of the processing gas inside the processing chamber; and
a controller, wherein:
in a state where a substrate, having a concave-convex structure and a dielectric film including silicon and nitrogen formed on the concavo-convex structure and having a non-uniform portion in a recess of the concavo-convex structure, is placed on the stage inside the processing chamber,
the controller performs a process that includes controlling the gas supply mechanism to supply a gas including oxygen into the processing chamber as the processing gas, and controlling the microwave introduction mechanism to generate first plasma of the gas including oxygen and expose the substrate to the first plasma, thereby forming a protective film including a cap layer that closes the non-uniform portion of the concavo-convex structure by bonding an upper side of the non-uniform portion.
